(19) United States
(12) Patent Application Publication
(10) Pub. No.: US 2001/0040263 A1
(43) Pub. Date: Nov. 15, 2001

(54) Microlens array and fabrication method thereof

(76) Inventor: Junichi Nakai, Fukuyama-shi (JP)

Correspondence Address: Dike, Bronstein, Roberts & Cushman, Intellectual Property Practice Group, EDWARDS & ANGELL, P.O. Box 9169, Boston, MA, 02209, US

(21) Appl. No.: 09/747,082

(22) Filed: Dec. 21, 2000

(30) Foreign Application Priority Data
Dec. 28, 1999 (JP) 11-373376

(51) Int. Cl. H01L 31/0232; H01L 27/14

(52) U.S. Cl. 257/432; 257/431

(57) ABSTRACT

In fabricating a microlens array, a transparent resin layer is formed on surfaces of microlenses by coating a phenol resin layer that chemically reacts with the microlenses and thereafter removing the phenol resin layer. Since the transparent resin layer is generated by chemical reaction with the microlenses, the transparent resin layer can be uniformly formed on the surfaces of the microlenses without deformation of the microlens and deterioration in material thereof. Therefore, the microlens array has the uniform microlenses in shape and quality, a short lens interval and a small ineffective region between the microlenses to obtain a high light condensation rate.

### BACKGROUND OF THE INVENTION

The present invention relates to a microlens array for use in a solid-state imaging device or the like and a method for fabricating the microlens array.

In general, the solid-state imaging device has a photoelectric conversion section and an electric charge transfer section on a semiconductor surface, and therefore, a region for actually photoelectrically converting incident light into an electric signal is limited. Lately, as a method for increasing the sensitivity of the solid-state imaging device, there has been developed a technique for forming a microlens on the photoelectric conversion section and making the incident light efficiently converge on the photoelectric conversion section.

As one microlens fabricating method described above, there is, for example, the one as shown in FIG. 2A through 2D (Japanese Patent Publication No. SHO 60-59752). According to this fabricating method, first, as shown in FIG. 2A, a flattening layer 24 for flattening the surfaces of a photoelectric conversion section 22 and an electric charge transfer section 23 on a semiconductor substrate 21 is formed by covering the sections. Next, as shown in FIG. 2B, a thermosoftening resin having photosensitivity is coated on the flattening layer 24 to form a thermosoftening resin layer 25, and the surface of this resin layer 25 is subjected to photoetching by means of a photomask 26 having the desired pattern. By this operation, the thermosoftening resin layer 25 is partially removed above the electric charge transfer section 23 so as to be a boundary between microlenses described later, and thereby a thermosoftening resin pattern 27 having a rectangular parallelepiped shape is formed as shown in FIG. 2C. Subsequently, as shown in FIG. 2D, the thermosoftening resin patterns 27 are heated to be thermally melted, obtaining quasi-hemispheric microlenses 28 by a surface tension owned by the resin.

According to this fabricating method, the microlenses 28 obtained by thermal deformation are widened on the flattening layer 24 by taking advantage of the surface tension of microlens material. This arrangement has an advantage that the sensitivity of the solid-state imaging device can be increased by making the interval between adjacent microlenses 28 shorter than the processing limit of photolithography and by reducing the ineffective region between the microlenses 28.

There is another microlens fabricating method shown in FIG. 3A and 3B (Japanese Patent Laid-Open Publication No. HEI 10-206605). According to this fabricating method, as shown in FIG. 3A, an SiON film 39 is deposited by the plasma CVD method along the surfaces of, for example, microlenses 38 formed by the aforementioned conventional method. Through these processes, new microlenses 41 constructed of the microlenses 38 and the SiON film 39 are formed. This arrangement allows the microlenses 41 to form a shorter interval and a smaller ineffective region than those of the microlenses 38.

Otherwise, a transparent organic film 30 is formed on the microlenses 38 by the spin coating method, and thereby new microlenses 42 constructed of both the transparent organic film 30 and the microlenses 38 are formed, as shown in FIG. 3B. This arrangement allows the microlenses 42 to form a shorter interval and a smaller ineffective region than those of the microlenses 38.

The aforementioned conventional fabricating method shown in FIGS. 2A through 2D has a problem attributed to the quasi-hemispheric microlenses 28 formed by thermally deforming with heat the rectangular parallelepiped thermosoftening resin pattern 27.

That is, it is very difficult to obtain microlenses having a uniform shape and a small ineffective region by thermally deforming with heat the rectangular parallelepiped thermosoftening resin pattern 27. There occurs, for example, the phenomenon that the resin is excessively melted during heating, causing the phenomenon of fusion of adjacent microlenses. As described above, if the microlenses are joined together, then the light condensation rate of the microlenses in this portion is reduced to cause a pixel defect, significantly deteriorating the image quality of the solid-state imaging device. In particular, as the compacting and increase in number of pixels of the solid-state imaging device progress, it is becoming harder to form microlenses of satisfactory uniformity with high yield by reducing the interval between microlenses as far as possible.

On the other hand, the aforementioned latter conventional methods shown in FIGS. 3A and 3B are a method for providing microlenses of a reduced ineffective region between microlenses and is proposed for solving the aforementioned problems of the former. However, another problem newly occurs according to this method.

That is, when forming the transparent film 39 to be formed on the surface of the microlenses 38 by the plasma CVD method as shown in FIG. 3A, the organic film is deposited at an elevated temperature while suffering physical damages due to plasma, and therefore, the shape of the foundational microlenses 38 sometimes inevitably suffers fatal defects (surface roughness and scratches, for example). If a color filter exists in a layer underneath the microlenses 38, this color filter is disadvantageously discolored by the heat of plasma. If the plasma energy and temperature are reduced to alleviate the deposition conditions in order to avoid the discoloration, then the adhesion of the transparent film 39 to the microlenses 38 becomes degraded to cause the exfoliation of the film and deterioration in film quality.

If the transparent film 39 is formed of the organic film by the spin coating method, as shown in FIG. 3B, then the organic film 30 stays between the microlenses 38 to deform the microlenses 42 as a whole, extremely degrading the light condensation rate of the microlenses.

### SUMMARY OF THE INVENTION

Accordingly, the object of the present invention is to provide a microlens array that has a short lens interval and a small ineffective region and causes no deterioration in lens shape and lens material and a method for fabricating the microlens array.

In order to achieve the aforementioned object, the present invention provides a microlens array having a plurality of microlenses formed of a transparent resin, wherein a surface of the microlenses is uniformly covered with a transparent resin layer.

According to this invention, the ineffective region of the microlenses can be reduced by uniformly covering the surfaces of the microlenses with the transparent resin layer, allowing a microlens array of high light condensation rate to be obtained.

In a microlens array of one embodiment, the transparent resin layer is generated by a chemical reaction with the microlenses.

According to this embodiment, since the transparent resin layer is a transparent resin layer generated by chemical reaction with the microlenses, the transparent resin layer can be formed to a uniform thickness on the surfaces of the microlenses, providing a microlens array that has a short lens interval and a small ineffective region causing no deterioration in lens shape and lens material.

In a microlens array of another embodiment, the transparent resin layer has a refractive index higher than a refractive index of the microlenses.

According to this embodiment, the refractive index of the transparent resin layer is higher than the refractive index of the microlens, and therefore, the focal distance of the microlens can be optimized to allow the light condensation rate to be made higher.

In a microlens array of one embodiment, the transparent resin layer contains a metal oxide.

According to this embodiment, the transparent resin layer contains a metal oxide (zirconium oxide, for example) to provides a film of a high refractive index. The focal distance of the microlens can be optimized by increasing the refractive index of the transparent resin layer, allowing the light condensation rate to be made higher.

In a microlens array of another embodiment, the transparent resin layer has a refractive index lower than a refractive index of the microlenses.

According to this embodiment, the refractive index of the transparent resin layer is lower than the refractive index of the microlens, and therefore, reflection light reflected on the microlens surface can be suppressed, allowing a microlens array of a higher light condensation rate to be obtained.

In a microlens array of one embodiment, the transparent resin layer contains fluorine atoms.

According to this embodiment, the transparent resin layer contains the fluorine atoms, and therefore, the refractive index of the transparent resin layer is made lower than the refractive index of the microlens, and thereby the reflection light reflected on the microlens surface can be suppressed.

The present invention also provides a microlens array fabricating method comprising the steps of: processing a microlens material layer into a pattern corresponding to a plurality of microlenses; forming the material layer into the plurality of microlenses by reflow of the material layer processed according to the pattern; and uniformly forming a transparent resin layer along the surface of the plurality of microlenses.

According to this invention, uniformly forming the transparent resin layer along the surfaces of the plurality of microlenses allows a microlens array to have a short interval between the transparent resin layers covering individual microlenses and a small ineffective region between the microlenses. Therefore, a microlens array having a high light condensation rate can be obtained. If this microlens array is formed into, for example, a solid-state imaging device, then the sensitivity of the solid-state imaging device can be increased.

According to the microlens array fabricating method of this embodiment, when forming microlens resin patterns in the positions corresponding to the plurality of microlenses, the interval between the resin patterns for the lenses can be set long. Therefore, the fusion of adjacent microlenses can be prevented to allow a microlens array of a uniform shape to be formed.

According to the microlens array fabricating method of one embodiment, the transparent resin layer is formed by coating an organic film that chemically reacts with the plurality of microlenses on the surface of the microlenses and removing the organic film.

According to this embodiment, the transparent resin layer formed on the microlens surface is a transparent resin layer generated by chemical reaction with the foundational microlenses, and therefore, this transparent resin layer can be uniformly formed on the microlens surface. When forming the transparent resin layer, no expensive fabricating device is needed and the foundational microlenses suffer almost no damage, and therefore, a microlens array of a uniform shape can be formed at low cost. The refractive index of the resin layer can be set either higher or lower than that of the microlens according to the type of the organic film to be coated on the microlens surface, and therefore, a microlens array having the desired light condensation rate can be formed.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIGS. 1A through 1F are schematic sectional views sequentially showing processes of a microlens array fabricating method according to an embodiment of the present invention;

FIGS. 2A through 2D are schematic sectional views sequentially explaining processes of a prior art microlens array fabricating method;

FIG. 3A is a sectional view showing a prior art microlens array;

FIG. 3B is a sectional view of another prior art microlens array; and

FIG. 4 is a graph showing examples of a relation between a coating film thickness of an organic film and a generated film thickness of a reaction layer in the above embodiment.

### DETAILED DESCRIPTION OF THE PREFERRED EMBODIMENTS

The present invention will be described in detail below on the basis of the embodiments thereof shown in the drawings.

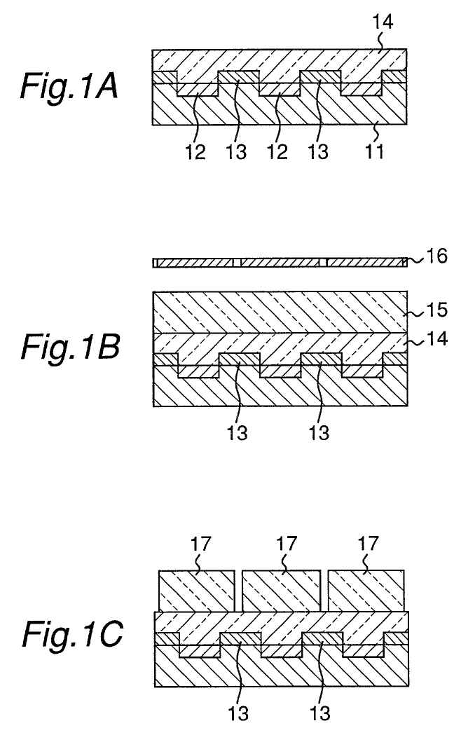

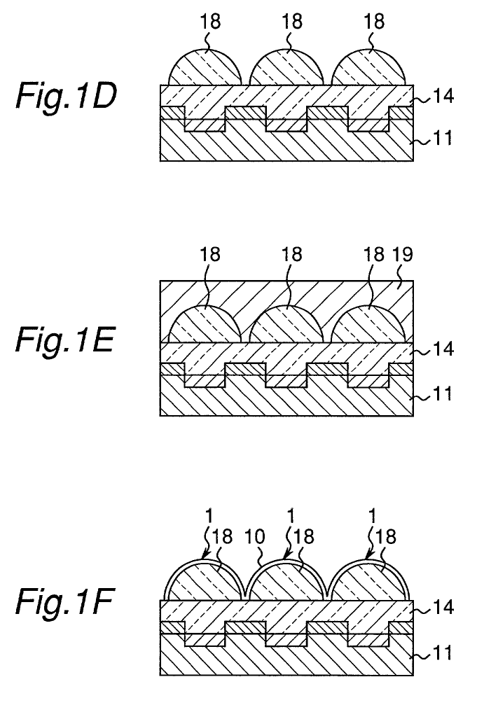

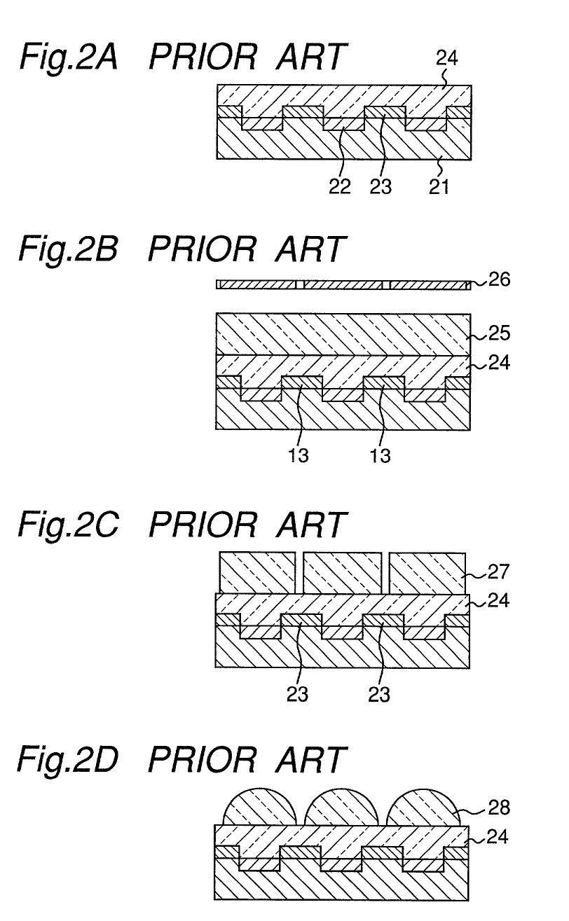

A microlens array fabricating method according to the present invention will be described with sequential reference to FIGS. 1A through 1F.

First, as shown in FIG. 1A, a flattening layer 14 is formed on a semiconductor substrate 11. This flattening layer 14 covers a photoelectric conversion section 12 and an electric charge transfer section 13 to provide a flat surface. Next, as shown in FIG. 1B, a thermosoftening resin having photosensitivity is coated on the flattening layer 14 to form a thermosoftening resin layer 15. This thermosoftening resin layer 15 is subjected to photoetching by means of a photomask 16 having the desired pattern.

Through the photoetching process, the thermosoftening resin layer 15 located above the electric charge transfer sections 13 is partially removed to be a boundary between microlenses and to form parallelepiped thermosoftening resin patterns 17 having a rectangular parallelepiped shape, as shown in FIG. 1C. In this case, the interval between adjacent patterns 17 is set to 0.6 μm. The thermosoftening resin layer 15 to be used in this case should preferably have a thermosetting property with an added thermosetting agent or the like (refer to Japanese Patent Laid-Open Publication No. HEI 04-012568).

Next, the thermosoftening resin patterns 17 are heated to be thermally melted, reflowed and concurrently thermally hardened, obtaining quasi hemispheric microlenses 18 as shown in FIG. 1D. In this stage, the interval between adjacent microlenses 18 is set to 0.4 μm. Next, as shown in FIG. 1E, a phenol resin layer 19 is spin-coated to a film thickness of 3.5 μm on the surface of the microlenses 18. This phenol resin layer 19 is provided by, for example, AZ Protectcoat-S (product name: Clariant Japan Co., Ltd.).

Subsequently, the resulting material is heated at a temperature of 100° C. for three minutes by means of a hot plate, then immersed in isopropyl alcohol for three minutes at room temperature and dried at a temperature of 150° C. for one hour by means of an oven. Consequently, as shown in FIG. 1F, a transparent resin layer 10 having an approximately uniformed thickness is formed on the surfaces of the microlenses 18 and the flattening layer 14 between the microlenses 18 in portions brought in contact with the phenol resin layer 19. This transparent resin layer 10 and the microlenses 18 constitute new microlenses 1. The interval between the new adjacent microlenses 1 is measured, and the measured value is 0.1 μm.

According to this embodiment, the new microlenses 1 formed by covering the surfaces of the microlenses 18 with the transparent resin layer 10 of the uniform thickness allows the ineffective region of the microlenses 1 to be reduced and allows a microlens array of a high light condensation rate to be obtained.

Furthermore, the transparent resin layer 10 is generated by chemical reaction with the foundational microlenses 18, and therefore, the transparent resin layer 10 can be uniformly formed on the surfaces of the microlenses 18 causing no deterioration in lens shape and lens material. Therefore, the ineffective region of the microlens array can be reduced, allowing a microlens array of a high light condensation rate to be fabricated.

Furthermore, a refractive index of the transparent resin layer 10 can be set either higher or lower than that of the microlens 18 according to the type of the organic film (phenol resin film 19 in this embodiment) to be coated on the surfaces of the microlenses 18. Therefore, according to this embodiment, a microlens array having the desired light condensation rate can be formed. When forming the transparent resin layer 10, no expensive fabricating device is needed and the foundational microlenses 18 suffer almost no damage, and therefore, a microlens array of the totally uniformed shape can be formed at low cost.

Additional reference is herein made to the processes of FIGS. 1E and 1F that are the point of this embodiment.

In general, if the organic film (phenol resin film 19) is coated on the polymer resin film (foundational microlenses 18), heated to a temperature of 80 to 150° C. and thereafter removed by an organic solvent or the like, then the reaction layer (transparent resin layer 10) generated by the chemical reaction with the organic film is formed on the polymer resin film. The thickness of this generated reaction layer is determined depending on the coating film thickness of the organic film and the type of the polymer resin film that serves as the foundation and has no relation to the type of the solvent for removing the organic film. If an organic film having a phenolic hydroxyl group is coated on, for example, the polymer resin film having an epoxy radical and heated at a temperature of 100° C. for three minutes on a hot plate, then the epoxy radical is made to be open-circular by the hydroxyl group, causing an ether linkage. As a result, a transparent reaction layer is formed on the polymer resin film. This reaction layer cannot be dissolved in an organic solvent of acetone, isopropyl alcohol or the like and is not deteriorated at all even when subjected to heat treatment at an elevated temperature of 200° C.

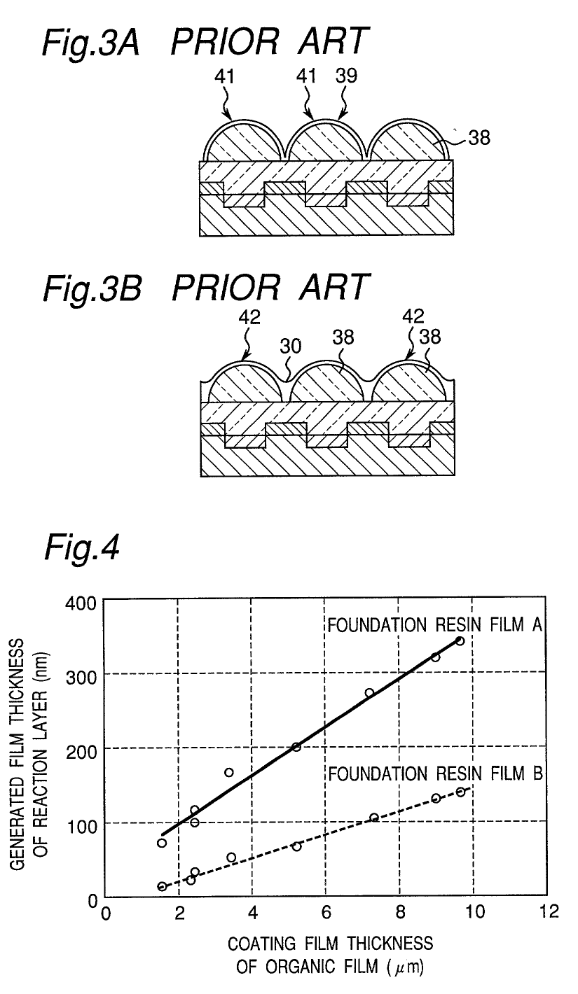

As an example, FIG. 4 shows a relation between the generated film thickness of the reaction layer and the coating film thickness of the organic film when phenol resin is employed as the organic film with regard to the case where a foundation resin film A is employed and the case where a foundation resin film B is employed. It was discovered that the generated film thickness of the reaction layer was thicker as the heating temperature when performing heating after coating the organic film on the foundation resin film A or B was higher. However, the generated film thickness of the reaction layer became excessively thick to deteriorate the intra-wafer film thickness uniformity when this heating temperature was raised, and therefore, the temperature was set to 80 to 150° C. in this embodiment as described hereinabove.

It is to be noted that the refractive index of the transparent resin layer 10 can be increased to allow the focal distance of the microlens 1 to be optimized by providing the transparent resin layer 10 by a film of a high refractive index containing a metal oxide (zirconium oxide, for example), allowing the light condensation rate to be made higher. If the transparent resin layer 10 has a fluorine atom in the aforementioned embodiment, the reflection light to be reflected on the microlens 1 can be suppressed by making the refractive index of the transparent resin layer 10 lower than the refractive index of the microlens 18.

The invention being thus described, it will be obvious that the invention may be varied in many ways. Such variations are not be regarded as a departure from the spirit and scope of the invention, and all such modifications as would be obvious to one skilled in the art are intended to be included within the scope of the following claims.

What is claimed is:

1. A microlens array having a plurality of microlenses formed of a transparent resin, wherein
a surface of the microlenses is uniformly covered with a transparent resin layer.

2. A microlens array as claimed in claim 1, wherein
the transparent resin layer is generated by a chemical reaction with the microlenses.

3. A microlens array as claimed in claim 2, wherein
the transparent resin layer has a refractive index higher than a refractive index of the microlenses.

4. A microlens array as claimed in claim 2, wherein
the transparent resin layer contains a metal oxide.

5. A microlens array as claimed in claim 2, wherein
the transparent resin layer has a refractive index lower than a refractive index of the microlenses.

6. A microlens array as claimed in claim 2, wherein
the transparent resin layer contains fluorine atoms.

7. A microlens array fabricating method comprising the steps of:
processing a microlens material layer into a pattern corresponding to a plurality of microlenses;
forming the material layer into the plurality of microlenses by reflow of the material layer processed according to the pattern; and
uniformly forming a transparent resin layer along the surface of the plurality of microlenses.

8. A microlens array fabricating method as claimed in claim 7, wherein
the transparent resin layer is formed by coating an organic film that chemically reacts with the plurality of microlenses on the surface of the microlenses and removing the organic film.
